(19) United States
(12) Patent Application Publication
(10) Pub. No.: US 2024/0132088 A1
(43) Pub. Date: Apr. 25, 2024

(54) SIMULATION BASED METHOD AND DATA CENTER TO OBTAIN GEO-FENCED DRIVING POLICY

(71) Applicant: HUAWEI TECHNOLOGIES CO., LTD., Shenzhen (CN)

(72) Inventors: Yann Koeberle, Boulogne Billancourt (FR); Stefano Sabatini, Boulogne Billancourt (FR); Dzmitry Tsishkou, Boulogne Billancourt (FR)

(21) Appl. No.: 18/526,627

(22) Filed: Dec. 1, 2023

Related U.S. Application Data
(63) Continuation of application No. PCT/EP2021/074878, filed on Sep. 10, 2021.

(51) Int. Cl. B60W 50/06; B60W 60/00; G05B 17/02

(52) U.S. Cl. CPC B60W 50/06; B60W 60/0015; G05B 17/02; B60W 2556/45

(57) ABSTRACT

A method updates a target driving policy for an autonomous vehicle at a target location. The method includes the steps of obtaining, by the vehicle, vehicle driving data at the target location; transmitting, by the vehicle, the obtained vehicle driving data and a current target driving policy for the target location to a data center; performing, by the data center, traffic simulations for the target location using the vehicle driving data to obtain an updated target driving policy; and transmitting, by the data center, the updated target driving policy to the vehicle.

### CROSS-REFERENCE TO RELATED APPLICATIONS

This application is a continuation of International Application No. PCT/EP2021/074878, filed on Sep. 10, 2021, the disclosure of which is hereby incorporated by reference in its entirety.

### FIELD

The present disclosure relates to a method for providing a driving policy for an autonomous vehicle.

### BACKGROUND

Simulations have been utilized in the prior art in order to improve safety of autonomous vehicles. Such simulations can be performed either in an online or offline manner.

In order to improve safety and confidence of real world driving policies, online solutions were proposed. For example, simulations can be performed by inserting in real time virtual objects in a scene during real driving experiments in order to challenge the autonomous vehicle driving policy. This enables to work in a risk free setting even if the real vehicle crash with virtual ones. However interactions with virtual vehicles are limited because virtual vehicles take decisions based on hard coded rules. Furthermore other vehicles in real scene cannot interact with the virtual ones, which biases the whole experiment. Consequently online testing with virtual vehicles cannot handle multiple real drivers which limits the space of scenarios available for safety evaluation.

As a conclusion online testing with virtual agents cannot be used to safely improve interactions with agents but is rather suited to reveal failure cases.

Previous other approaches already used offline traffic simulation in order to test and improve safety of a driving policy.

Example from the prior art use simulation based on logged data (also referred to as log in the following) collected by the self-driving vehicle in the real world. The simulation is initialized based on the logged data but some agents of the log are replaced with simulated agents learnt separately in a completely different setting. During the simulation, the goal is to analyze how the autonomous vehicle driving policy would have reacted with respect to simulated agents that are designed to behave differently than original ones.

This process enables to check how robust the driving policy is with respect to a slight scenario perturbation. However, the original agent from the traffic cannot interact realistically with the simulated one because they just replay logs with some simple safety rules. Consequently, as simulation goes on, it becomes less and less realistic because simulated agents behave differently from logs which in turn makes the behavior of logged agents not realistic for the new perturbed situation.

As a conclusion, a simulation based on log with simulated agent substitution is less able to provide fully realistic interactions with a target driving policy which limits the possibility of improvement for the autonomous vehicle driving policy.

Further, there is a need for driving policies adapted to a specific location, in particular locations which may involve many other vehicles and/or many different types of interaction between the traffic agents and thus require special driving policies for an autonomous vehicle that are able to handle such location specific situations, as for example entering, driving through and exiting a particular roundabout.

### SUMMARY

In view of the above, aspects of the present application provide a procedure that enables to massively train an autonomous vehicle driving policy on one or more specific target geographical locations, making use of a realistic and interactive traffic generator.

According to a first aspect, a method of updating a target driving policy for an autonomous vehicle at a target location is provided, comprising the steps of obtaining, by the vehicle, vehicle driving data at the target location; transmitting, by the vehicle, the obtained vehicle driving data and a current target driving policy for the target location to a data center; performing, by the data center, traffic simulations for the target location using the vehicle driving data to obtain an updated target driving policy; and transmitting, by the data center, the updated target driving policy to the vehicle.

The autonomous vehicle obtains vehicle driving data at a specific location (target location). These data can be acquired by using sensors and/or cameras. Such logged vehicle driving data are transmitted to a data center that performs offline simulations for the target location. The traffic simulations train the current target driving policy for example by using simulated traffic agents that are included in the simulation scenario, in addition to traffic agents that are already included in the logged data, and which traffic parameters may be varied/perturbed. The target driving policy may be trained in simulations on multiple driving scenarios generated from one or more logged driving scenarios whose characteristics (i.e. initial positions, goal, spawning time, for example) are perturbed in such a way to challenge the driving policy. After the simulation step, the current target driving policy is updated based on the simulation results, and the updated target driving policy is transferred to the autonomous vehicle. Accordingly, the target driving policy is improved for the specific target location by using the vehicle driving data obtained at the target location. Therefore, when the vehicle next time passes through the target location, the updated (improved) target driving policy can be applied. Agents (traffic agents) may refer to other vehicles or pedestrians, for example.

According to an implementation, the steps of obtaining vehicle driving data at the target location, transmitting the obtained vehicle driving data to the data center, performing traffic simulations for the target location using the vehicle driving data to obtain an updated target driving policy, and transmitting the updated target driving policy to the vehicle may be repeated one or more times. The whole process may be repeated as long as necessary, for example until a sufficient security and/or confidence measure (score/metric) is reached.

In this way, by obtaining further vehicle driving data (real data), for example when the vehicle passes the target location the next time, and performing further simulations by a traffic simulator in the data center using the further vehicle driving data, the target driving policy can be updated progressively with few real data and a comparatively larger amount of simulation data in an offline manner. The target driving policy can thus be further trained and optimized to improve security of the autonomous driving.

According to an implementation, the method may comprise the further steps of obtaining general driving data and general traffic policies; and using the general driving data and the vehicle driving data to adapt the general traffic policies to the target location.

An initial general traffic simulator may be implemented with the general driving data and general traffic policies. By using the vehicle driving data at the target location, a fine-tuning of the general traffic simulator based on the (real) vehicle driving data from the target location can be performed by challenging the target driving policy on the target location through simulation, in particular simulated interactions of the vehicle with other traffic agents. As an example, real driving scenarios may be collected (log data) and a Scenario generator may generate a 1000 new scenarios from them in such a way to challenge the current traffic policies. A sequence of driving scenario perturbations may be found that maximize a failure rate, such as a crash rate for example. A failure can be characterized by a safety score and/or a confidence score being inferior to a threshold. In other words, a sequence of scenario driving perturbations may be obtained that minimize safety and/or confidence score of the traffic policies. Accordingly, the optimal scenario perturbation may be found by maximizing the failure rate of the driving policies on the generated scenarios. Such perturbations are most challenging and thus optimize the learning effect. Traffic policies may be rolled out on those new scenarios and further updated.

Once the traffic simulator is fine-tuned, it can be used to improve the target driving policy through simulation interaction on a massive number of synthetic driving scenarios based on the real scenario from the vehicle driving data and simulated (challenging) scenarios, for example generated by a challenging scenario generator. The target driving policy may be trained on a new driving scenario generated from a logged scenario in such a way to maximize the failure rate (alternatively minimize safety and or confidence score) of target policy given the updated traffic. In case traffic is responsible for a failure (such as a crash), the previous step is repeated otherwise it means that target driving policy was responsible for its failure (such as the crash) on the new driving scenario and this experience may be used to fine-tune the target policy. Driving scenarios may be generated based on a sequence of bounded perturbations applied on the original real logged driving scenario in such a way to maximize the crash rate on the sequence of new driving scenarios generated. If S₀ is the real scenario then (S₁, . . . S_{N}) may be the sequence of generated scenarios with slight incremental perturbation of S₀, i.e. S₁=S₀+perturbation₁, S₂=S₁+perturbation₂, etc. Let c(S,Π) denote the failure indicator of policy Π on scenario S then it is preferred to maximize Σᵢ₌₁^{N}c(Sᵢ,Π) where N denotes the length of sequence of perturbations. A perturbation is a modification of either initial position, goal location (destination), agent spawning time on the map, or a modification of a ratio that controls the aversion of risk of a traffic participant.

According to an implementation, the step of performing traffic simulations for the target location may be based on the adapted general traffic policies.

This has the advantage that the adapted (fine-tuned) general traffic policies can then be used to more precisely perform the further simulation steps.

According to an implementation, the updated target driving policy may comprise an updated set of target driving policy parameters.

The target driving policy may be described by target driving policy parameters, such that the updated target driving policy may be defined by one or more updated target driving policy parameters. In particular, only the updated parameters may be transmitted to the vehicle.

According to an implementation, the step of performing traffic simulations may comprise training the current target driving policy to improve a confidence measure and/or a safety measure.

A safety measure (safety metrics) can be determined based on at least one of an average rate of jerk, an average minimum distance to neighbors, a rate of off-road driving, or a time to collision. A confidence measure (confidence metrics) can be estimated based on at least one of an average time to reach a destination, an average time spent standstill, or an average longitudinal speed compared to expert driving scenario.

According to an implementation, the method may further comprise generating different traffic scenarios by modifying an initial traffic scenario obtained from the vehicle driving data; wherein the traffic simulations for the target location are performed with the generated different traffic scenarios. For example, a scenario generator may receive an initial set of real logged driving scenarios, a set of traffic policies to be challenged denoted Π, and a set of traffic policies that are not intended to be specifically challenged. The initial driving scenarios may be perturbed by generating the sequence of new driving scenarios (S₁, . . . , S_{N} as explained before) such that Σᵢ₌₁^{N}c(Sᵢ,Π) is maximum. Note that c(Sᵢ,Π) quantify failure based on safety and confidence metric Indeed when simulated with policies Π on Sᵢ the safety metric and confidence metric on this scenario for policies H may be obtained. Note that Π can be just the target policy (the last step of a pipeline further described below) or Π can be the traffic policies (the second step of the pipeline).

This defines the generation of challenging scenarios that are simulated by modifying a traffic scenario obtained from the vehicle driving data.

According to an implementation, the step of modifying the initial traffic scenario may comprise at least one of (a) increasing a number of agents in the traffic scenario; (b) modifying a velocity of an agent in the traffic scenario; (c) modifying an initial position and/or direction of an agent in the traffic scenario; and (d) modifying a trajectory of an agent in the traffic scenario.

This provides for possible specific ways for the generation of challenging scenarios. In particular, additional/new traffic agents can be inserted. Further or alternatively, the velocity of a traffic agent can be changed, for example by including perturbations around the measured velocity of an agent from the vehicle driving data or the velocity of an inserted agent, an initial position and/or a direction of an agent in the traffic scenario can be changed, in particular by perturbation around a current value, and/or the trajectory/path of the traffic agent can be changed, specifically perturbed. More particularly, the destination can be changed, and the routing may be done internally by the policy. Further, some features of the behavior for traffic policies such as the ratio of aversion of risk may be controlled.

According to an implementation, the target location may be described by map data of a geographically limited area.

The target location may be described by a bounded map, in particular a road network structure can be used for simulation. These map data may also include traffic signs, which may be predefined in the map data, or can be inserted from the vehicle driving data (e.g., identification by a camera of the vehicle) The position of the vehicle in the vehicle driving data may be obtained from a position determining module, a GPS module, for example, and the position can be related to the map data.

According to an implementation, vehicle driving data at the target location may further be obtained from one or more further vehicles.

In this implementation other vehicles of a fleet of vehicles may participate in providing vehicle driving data that can then be used for the simulations. This improves the simulation results regarding safety and/or confidence, and reduces the time for updating the target driving policy.

According to a second aspect, a data center is provided, comprising receiving means configured to receive, from a vehicle, vehicle driving data at a target location and a current target driving policy for the target location; processing circuitry configured to perform traffic simulations for the target location using the vehicle driving data to obtain an updated target driving policy; and transmitting means configured to transmit the updated target driving policy to the vehicle.

The advantages and further details of the data center according to the second aspect and any one of the implementations thereof correspond to those described above with respect to the method according to the first aspect and the implementations thereof. In view of this, here and in the following, reference is made to the description above.

According to an implementation, the processing circuitry may be further configured to use general driving data and the vehicle driving data to adapt general traffic policies to the target location.

According to an implementation, the processing circuitry may be further configured to perform traffic simulations for the target location based on the adapted general traffic policies.

According to an implementation, the updated target driving policy may comprise an updated set of target driving policy parameters.

According to an implementation, the processing circuitry may be further configured to train the current target driving policy to improve a confidence measure and/or a safety measure.

According to an implementation, the processing circuitry may be further configured to generate different traffic scenarios by modifying an initial traffic scenario obtained from the vehicle driving data; and to perform the traffic simulations for the target location with the generated different traffic scenarios. Regarding further details of generating different traffic scenarios, i.e., how to use a challenging scenario generator, reference is made to the explanations above with respect to the implementations, and to the detailed description of the embodiments below.

According to an implementation, the processing circuitry may be configured to modify the initial traffic scenario by at least one of (a) increasing a number of agents in the traffic scenario; (b) modifying a velocity of an agent in the traffic scenario; (c) modifying an initial position and/or direction of an agent in the traffic scenario; and (d) modifying a trajectory of an agent in the traffic scenario.

According to an implementation, the target location may be described by map data of a geographically limited area.

According to an implementation, the receiving means may be further configured to receive vehicle driving data at the target location from one or more further vehicles.

According to a third aspect, a system is provided, the system comprising a vehicle configured to obtain vehicle driving data at a target location, and configured to transmit the obtained vehicle driving data and a current target driving policy for the target location to a data center; and comprising a data center according to the second aspect or any one of the implementations thereof.

According to an implementation, the system may be configured to repeatedly perform the steps of obtaining vehicle driving data at the target location, transmitting the obtained vehicle driving data to the data center, performing traffic simulations for the target location using the vehicle driving data to obtain an updated target driving policy, and transmitting the updated target driving policy to the vehicle.

According to a fourth aspect, a computer program product is provided, the computer program product comprising computer readable instructions for, when run on a computer, performing the steps of the method according to the first aspect or any one of the implementations thereof.

Details of one or more embodiments are set forth in the accompanying drawings and the description below. Other features, objects, and advantages will be apparent from the description, drawings, and claims.

### BRIEF DESCRIPTION OF THE DRAWINGS

In the following, embodiments of the present disclosure are described in more detail with reference to the attached figures and drawings, in which:

FIG. 1 illustrates a method of updating a target driving policy for an autonomous vehicle at a target location according to an embodiment.

FIG. 2 illustrates a system including an autonomous vehicle and a data center according to an embodiment.

FIG. 3 illustrates a method according to an embodiment.

FIG. 4 illustrates a method according to an embodiment.

FIG. 5 illustrates a method according to an embodiment.

FIG. 6 illustrates a method according to an embodiment.

### DETAILED DESCRIPTION

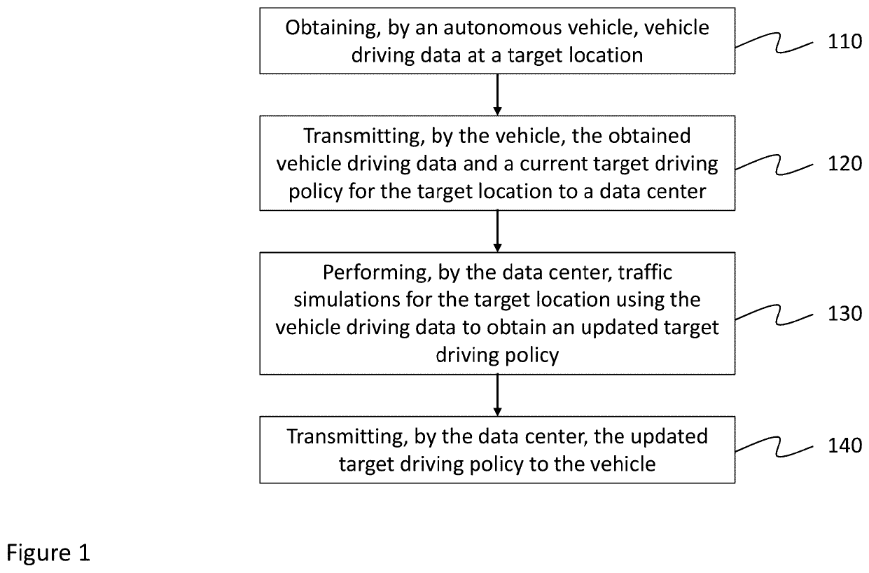

FIG. 1 illustrates a method of updating a target driving policy for an autonomous vehicle at a target location according to an embodiment. The method comprises the steps of

110: Obtaining, by the vehicle, vehicle driving data at the target location;

120: Transmitting, by the vehicle, the obtained vehicle driving data and a current target driving policy for the target location to a data center;

130: Performing, by the data center, traffic simulations for the target location using the vehicle driving data to obtain an updated target driving policy; and

140: Transmitting, by the data center, the updated target driving policy to the vehicle.

The autonomous vehicle obtains vehicle driving data at the target location. These data can be acquired by using sensors and/or cameras. The obtained vehicle driving data are transmitted to a data center that performs offline simulations for the target location. These traffic simulations train the target driving policy by using simulated traffic agents that are included in the simulation scenario, in addition to traffic agents that are already included in the vehicle driving data, and/or modifying traffic parameters of the agents, such as velocity. Accordingly, an initial scenario is perturbed and, for example, 1000 new scenarios are generated from it as already detailed above. After the simulations, the target driving policy is updated based on the simulation results and the updated target driving policy is transferred to the autonomous vehicle, such that the vehicle can apply the updated target driving policy when driving through the target location next time.

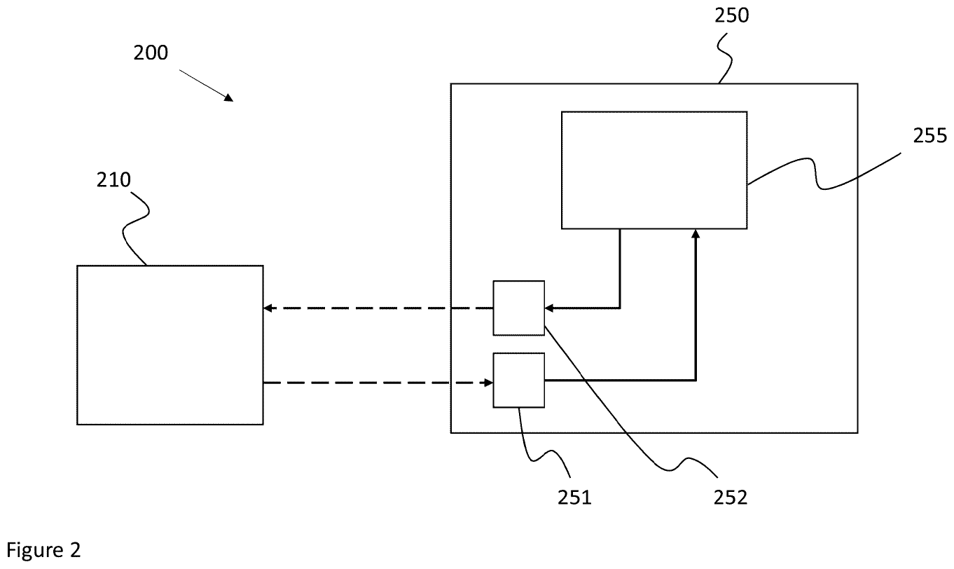

FIG. 2 illustrates a system including an autonomous vehicle and a data center according to an embodiment.

The system 200 comprises the vehicle 210 and the data center 250. The data center 200 comprises receiving means 251 configured to receive, from the vehicle 210, vehicle driving data at a target location and a current target driving policy for the target location; processing circuitry 255 configured to perform traffic simulations for the target location using the vehicle driving data to obtain an updated target driving policy; and transmitting means 252 configured to transmit the updated target driving policy to the vehicle 210.

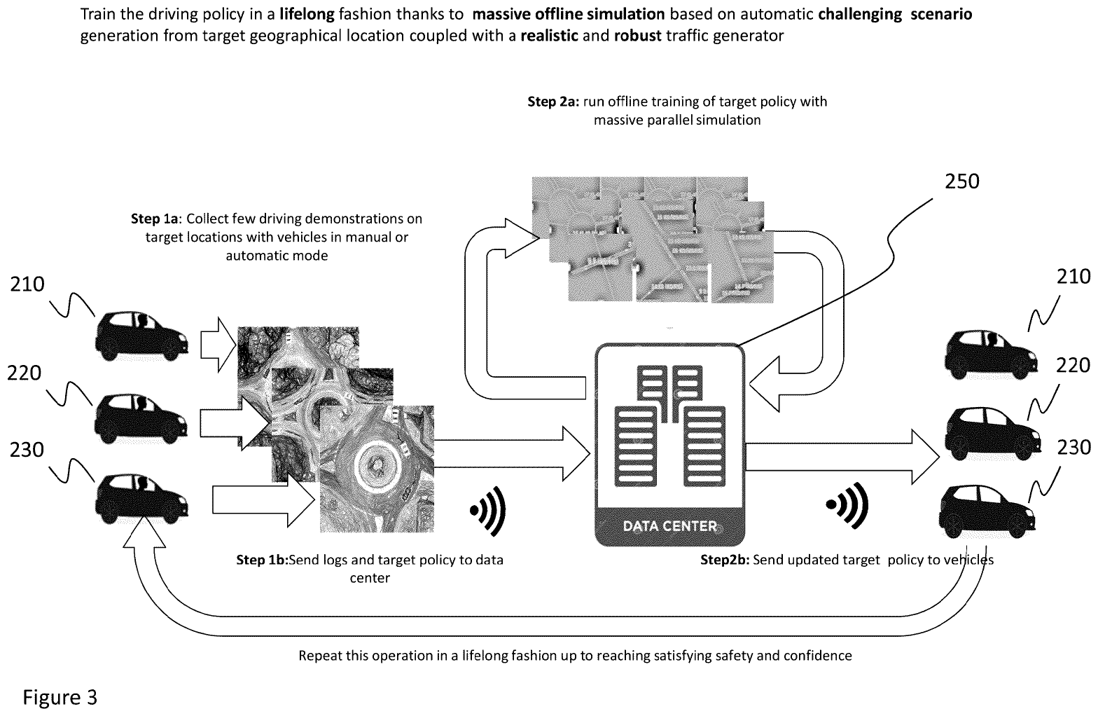

Further details of the present disclosure are described in the following with reference to FIGS. 3 to 6.

The present disclosure solves, among others, the technical problem of being able to improve safety and confidence of an autonomous vehicle driving policy with minimum data collection on a target geographical area, which is of prime interest for massive deployment of self-driving vehicles.

Indeed, the basic general driving policy of an autonomous vehicle is designed to be safe for any situation and is expected to be overcautious when exposed to unseen locations. In order to adapt the autonomous vehicle to the customer specific use case such that it become at least as efficient as a human driver, the target policy must be fine-tuned to the specific user location. As an autonomous vehicle driving company may have numerous customers on various locations whose dynamics evolve, this target policy fine-tuning must be done automatically to be profitable.

The present disclosure tackles the problem of automatically improving safety and confidence of a driving policy on target geographical areas in an offline fashion thanks to realistic and robust traffic simulation, fine-tuned in situ with minimum data collection and minimum human intervention.

The disclosure is based on a specific procedure that enables to massively train an autonomous vehicle driving policy on specific target geographical locations making use of a realistic traffic generator.

### General Process: Automatic Driving Experience Improvement

In practice, this method enables the end user of the autonomous vehicle, to experience a sudden improvement in confidence of driving and safety on specific target location of interests (e.g. the daily commute from home to work) after only a limited data collection in situ (at the target location).

It is now described how the offline training pipeline can be used for real applications in FIG. 3. Multiple Self Driving Vehicles (SDV) 210, 220, 230 are considered that are deployed on specific locations depending on user's activity. Each of those vehicles is collecting logs (vehicle driving data) during travels every days either in manual or automatic driving mode. Those logs can be sent remotely to a data center (during night for example).

In the data center, a massive amount of simulations in the specific target locations are performed where the autonomous driving policy can experience very diverse situations. The autonomous driving policy is trained and improved using this massive amount of experiences collected in simulation.

Once a concrete improvement in confidence and safety of the autonomous driving policy is measured in simulations, an updated autonomous vehicle driving policy will be sent back automatically to the vehicle 210, 220, 230 through remote communication. During next travels the vehicle (e.g., car) will be able to drive according to the updated driving policy and the user will experience improvements if re-visiting previously seen locations or may just continue to collect experience if new locations are encountered.

An important part of the present disclosure resides in the simulation process. The massive amount of simulations are not driven by hard coded rules as in previous work, but a realistic and interactive traffic is learned using large amount of data and is fine-tuned on specific locations of interest.

The major advantages of such an architecture are:
Automatic autonomous vehicle driving policy update with minimal data collection and human support on target locations
Massive interaction with a traffic simulator for quantitative safety evaluation
Simulation is realistic and efficient because it is performed by leveraging massive data and fine-tuning to specific target locations

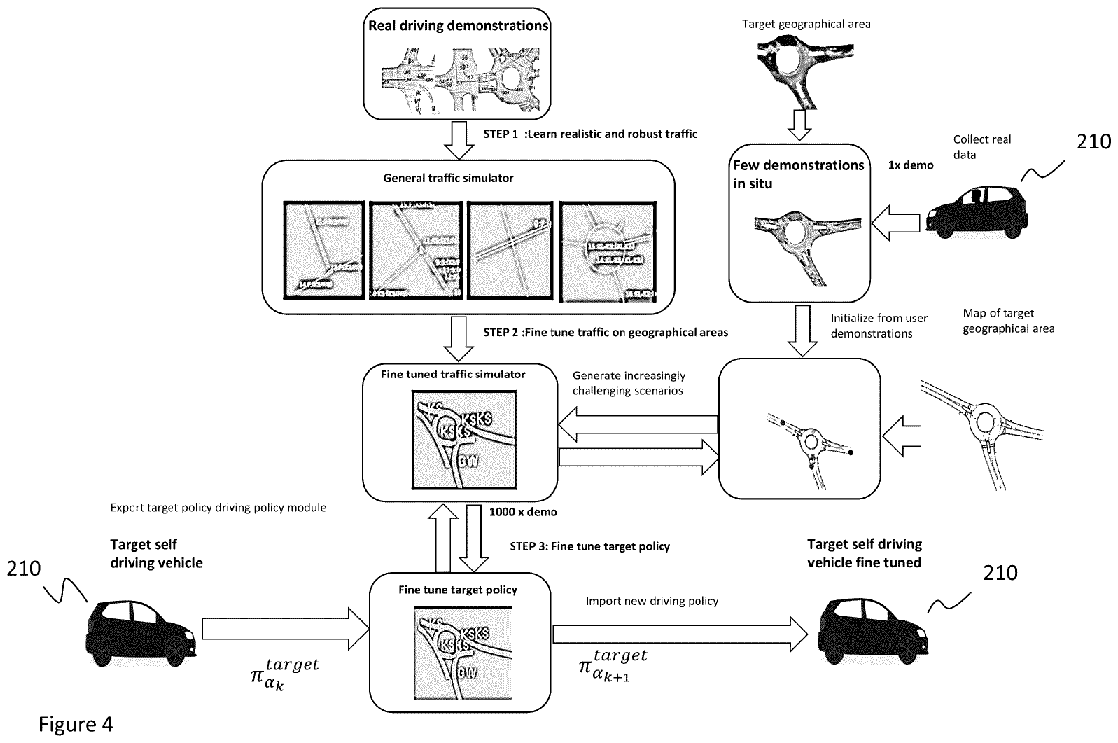

The process of learning a realistic traffic simulation can be divided in three steps as depicted in FIG. 4.
General realistic traffic learning
Traffic fine-tuning on target geographical locations
Autonomous vehicle driving policy learning on target locations interacting with the learned traffic

These steps are further described in detail in the following.

### 1) General Realistic and Robust Traffic Learning

The main idea of this first step is to leverage the massive amount of data that autonomous driving companies have available (though fleets or crowdsource data collection) to learn a general realistic traffic.

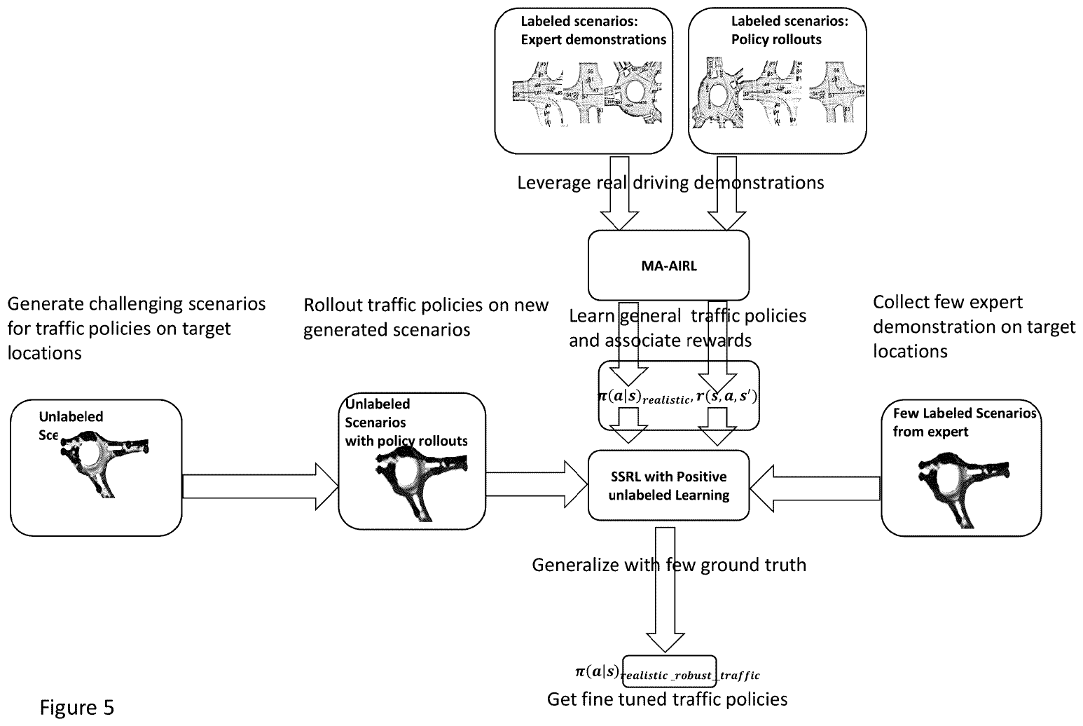

As shown in FIG. 5, given a dataset of driving demonstration we learn a pool of driving policies along with their respective reward function based on multi agent generative adversarial imitation learning MAIRL [as described in the reference Song et al, 2018]. The multi agent learning enable to learn interactions among agents on a large number of situations generated based on collected real crowdsourced data on the available locations. At the end of this process, traffic polices are obtained that reproduce realistic driving behaviors on available locations.

### 2) Traffic Fine-Tuning on Target Location

The goal of this step is to fine-tune the general traffic learned at step 1 on few geo-fenced locations (locations that are limited by boundaries) that will be the primary target for the autonomous vehicles user.

In order to fine-tune the traffic policies on specific geographical locations the following procedure is applied.

First the collection of few driving demonstrations is performed on target locations either in manual or in automatic driving mode with the real vehicle. It can be done by the autonomous driving company or directly by the user that carry out this procedure while it is using its own vehicle in daily life. Logs are subsequently sent to the data center and directly trigger a traffic fine tuning phase. Contrary to step 1, only few demonstration are needed on this locations.

During the traffic fine-tuning phase PU-GAIL [Positive-Unlabeled Generative Adversarial Imitation Learning, see reference Xu et al, 2019] may be used to adapt the general traffic learned in Step 1 to the target locations. PU-GAIL enables to leverage both the few collected real driving demonstration in the area and synthetic generated driving simulation in the target geographical area to adapt the traffic policies.

A few demonstrations may be collected and then challenging scenarios generated from those initial scenarios in such a way to maximize the failure rate of the current traffic policies on those new generated scenarios. The simulation rollouts generated on synthetic scenarios can be used to update traffic policies based on PU-GAIL procedure. As stated, not a lot of expert data on the target location is required, because the PU-GAIL formulation enables to learn in those kind of situations.

At the end of this phase the traffic is able to interact safely on the target locations.

### 3) Target Policy Fine-Tuning

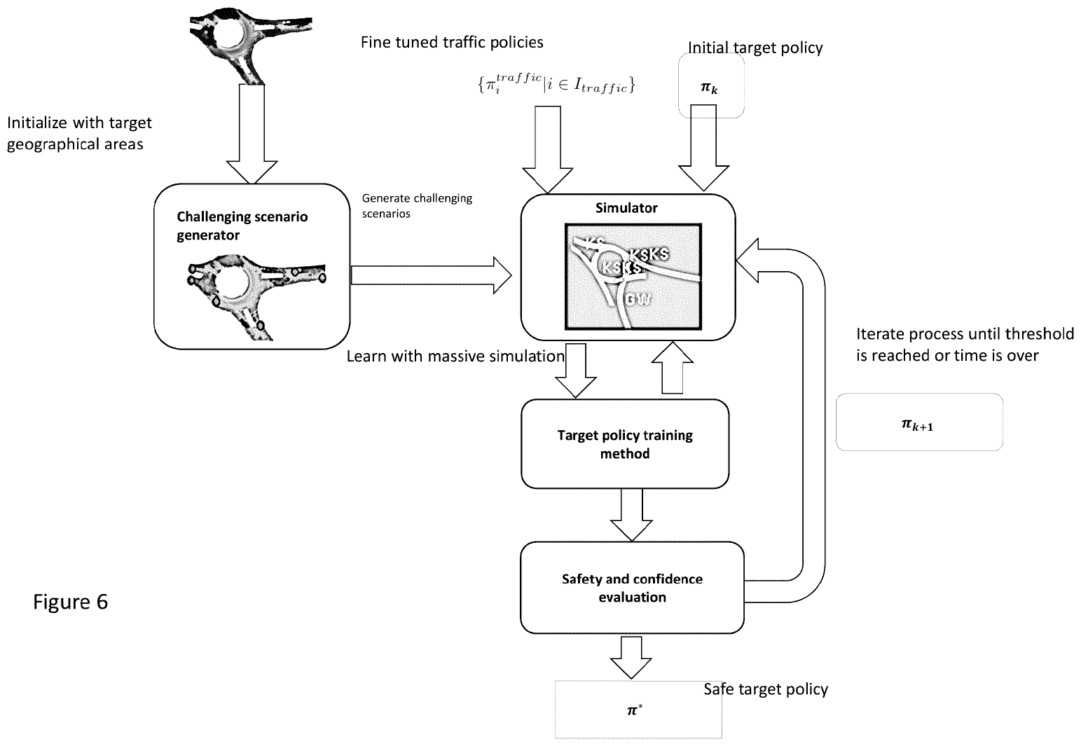

The third step consists in learning the actual autonomous vehicle driving policy on the target locations, as shown in FIG. 6.

This is done by making the autonomous vehicle interact with the learned traffic in simulations.

This process enables the driving system to learn using a great amount of diverse driving situations that do not need to be explicitly logged or tested in autonomous mode because they are simulated.

Contrary to previous work where simulation was made in a rule based manner, the traffic here is simulated in a realistic manner because learned and fine-tuned with data on specific target locations in step 2.

Here again, the scenario generator is used to generate challenging scenarios for the target policy given the actual fine-tuned traffic. Once the failure rate on the set of synthetic scenarios is high enough, those experiences are used to update the driving policy.

After this step the policy update is sent back to real vehicle through remote communication and the customer driver can experiment improvement during next travels.

The vehicle 210, 202, 230 is a self-driving vehicle (SDV) equipped with remote communication and sensors. The data center has a communication interface to communicate with the SDV.

The algorithm used in the data center requires a HD Map of the target locations and a dataset of driving demonstrations, and a GNSS (global navigation satellite system) and a IMU (Inertial Measuring Unit) and/or Vision with HD map based localization capabilities for target vehicle data collection.

A database for training the system may require a large scale database of driving demonstrations aligned with the HD map on multiple locations.

The system can be used for improving confidence and safety of the autonomous driving policy on target geographical locations with minimum in situ data collection.

The method according to the present disclosure is based on main training procedure that improve safety and confidence of a target driving policy denoted π_{α}^{target} a target used in automatic driving mode on real vehicles by users. We first introduce some notations and vocabulary relative to the training pipeline detailed above and then turn to in depth description of the main three steps detailed above.

The training procedure is based on a driving simulator that is used to generate driving simulations. The driving simulator is initialized with a driving scenario S and a set of driving policies Π_{θ}. A driving scenario S=(R, T, H) is defined as combination of a bounded road network description on a specific geographical area, a traffic flow T defined on R, and a simulation horizon H. The simulation horizon determines the maximum number of simulation steps before the simulator is reset to a new scenario. The traffic flow populates the driving scene with agents at specific frequencies. Additionally, it attributes to each spawned agent its initial physical configuration, its destination, its type (i.e. car, bicycle, pedestrian) and its associated driving policy π_{θ} ∈ Π_{θ}. Each agent is animated by a driving policy denoted π_{θ} implemented as a neural networks that associates at each simulation steps an action a conditioned on the route r to follow and the ego observation of the scene o according to probability distribution π_{θ}(a|o, r). The route is provided automatically by the simulator based on R and the destination. Ego observation are generated by simulator from each agent's point of view and is mainly composed of semantic layers i.e. HD Maps and semantic information about the scene context i.e. distance to front neighbors, lane corridor polylines etc. An action consist in a high level description of the ideal trajectory to follow during at least the whole simulation step. Note that each action is converted into a sequence of controls by a lower level controller to meet the physical constrains of the agent i.e. car, truck, pedestrian etc. A driving simulation based on scenario S=(R, T, H) generates multi agent trajectories Γ composed of single agent trajectories for all agents populated between temporal range [0, H]. A single agent trajectory τ=[(o₀, a₀), . . . , (o_{T}, a_{T})] is primarily a sequence of ego agent observation and action sampled at each simulation step with a given temporal length T. We call traffic policies the set of policies

$${\prod }_{θ} = {\{ {π}_{{θ}_{i}} \}}_{i ∈ N}$$

learned for animating agents populated by the traffic flow of the driving scenarios as opposed to target driving policy π_{α}^{target} that controls real self driving vehicles. Note that several traffic agent can be controlled by the same driving policy model. Additionally we introduce expert driving demonstration

$${D}_{e} = {\{ ( {S}_{i}^{e} , {Γ}_{i}^{e} ) \}}_{i ∈ {I}_{{D}_{e}}}$$

coming from large scale dataset as a set of pairs (Sᵢ,Γᵢ^{e}) composed of a driving scenario Sᵢ^{e} and the associate multi agent expert trajectories Γᵢ^{e} that contains trajectories of each expert agents populated in Sᵢ^{e} during scenario temporal extension. In order to improve the target policy π_{α}_{ₖ}^{target} on target locations represented by their road networks

$${\{ {R}_{i}^{target} \}}_{i ∈ {I}_{target - locations}}$$

we leverage a few user demonstrations collected progressively on target location and denoted

$${D}_{user} = {\{ ( {S}_{i}^{user} , {Γ}_{i}^{user} ) \}}_{i ∈ {I}_{{D}_{user}}} .$$

### Step 1: General, Realistic and Robust Traffic Learning

The first step consists in learning traffic policies

$${\prod }_{θ} = {\{ {π}_{{θ}_{i}} \}}_{i ∈ N \_ traffic}$$

from driving demonstrations

$${D}_{e} = {\{ ( {S}_{i} , {Γ}_{i}^{e} ) \}}_{i ∈ {I}_{{D}_{e}}}$$

along with their reward functions rᵢ thanks to multi agent adversarial imitation learning MAIRL [Song et al 2018]. The MAIRL algorithm solves the following optimization problem.

$${min}_{θ} {max}_{ϕ} \text{?} {\sum }_{i = 1}^{{N}_{traffic}} log ( \text{?} ( \text{?} ) ) + \text{?} {\sum }_{i = 1}^{{N}_{traffic}} ( log ( 1 - \text{?} ( \text{?} ) ) - \text{?} ( ϕ )$$

$$\text{?} \text{indicates text missing or illegible when filed}$$

Here Ψ is a regularization term. Note that each traffic policy π₇₄ _{ᵢ} of

$${\prod }_{θ} = {\{ {π}_{{θ}_{i}} \}}_{i ∈ {N}_{traffic}}$$

has its associate reward function r_{ϕ}_{ᵢ} that maps each pair of observation oₜ and action aₜ to a real value that indicates how realistic and safe the agent behaves. The optimization problem is solved alternating between optimizing the discriminators D_{ϕ}_{ᵢ} and optimizing the policy π_{θ}_{ᵢ} with a policy update method like PPO, SAC, TD3, D4PG [see Orsini et al 2021]. The reward function is derived from the discriminator as detailed in [Fu et al, 20189 with r_{ϕ}(s,a)=log(D_{ϕ}(o,a)]−log(1−D_{ϕ}(o,a)) . In order to obtain diverse behaviour a mutual information regularization Ψ can be used [Li et al, 2017]. Enforcing domain knowledge is possible thanks to complementary losses [Bhattacharyya et al, 2019] that penalizes irrelevant actions and states or thanks to constrains to leverage task relevant features [Zolna et al, 2019; Wang et al, 2021]. Implicit coordination of agent is possible thanks to the use of a centralized critic D_{centralized} instead of individual D_{ϕ}_{ᵢ} in order to coordinate all agent actions at a given state as detailed in [Jeon et al, 2021]. This is especially interesting when agents need to negotiate like in an intersection where one agent needs to give the ways while the other should take the way. At the end of this process we obtain general realistic and robust traffic policies

$${\prod }_{θ} = {\{ {π}_{{θ}_{i}} \}}_{i ∈ {N}_{traffic}} .$$

### Step 2: Traffic Fine Tuning on Target Location

Once the traffic policies

$${\prod }_{θ} = {\{ {π}_{{θ}_{i}} \}}_{i ∈ {N}_{traffic}}$$

are trained from demonstrations Dₑ, the second step consists in fine tuning traffic policies on target geographical locations such that traffic agent can interact safely on target locations in various situations beyond the ones encountered by users in Dᵤₛₑᵣ. Leveraging few user demonstrations

$${D}_{user} = {\{ ( {S}_{i} , {Γ}_{i}^{user} ) \}}_{i ∈ {I}_{{D}_{User}}}$$

collected by users on target locations

$${\{ {R}_{i}^{target} \}}_{i ∈ {I}_{target - locations}} ,$$

a scenario generator generates increasingly challenging scenarios Sₖ^{challenging} for the traffic policies Π_{θ} over which traffic policies are trained. The synthetic demonstrations Dₖ^{synthetic} generated by traffic policies have no associate real expert demonstration, contrary to the previous steps where traffic policies generated trajectories over scenario Sᵢ^{e} endowed with expert reference trajectories Γᵢ^{e} because (Sᵢ,Γᵢ^{e}) ∈ Dₑ. Consequently we adapt the training method of the traffic polices in order to leverage unlabeled trajectories of Dₖ^{synthetic} as well as few labeled trajectories in Dᵤₛₑᵣ based on PUGAIL [Xu et al, 2019] procedure, detailed in an additional section.

An example schematic code for traffic fine-tuning is shown below as Algorithm 1.

Algorithm 1 Traffic fine tuning

```
INPUT:
  few driving demonstrations on target locations [symbol]  ᵤₛₑᵣ =
  {(Sᵢ, τᵢ^{user})}|_{iϵD}_{ᵤₛₑᵣ}
  general traffic policies Π_{θ}_{₀} and associate reward functions R_{ϕ}
  minimum safety and confidence score Score_{theshold}
OUTPUTS:
  fine taned traffic policies
  ${\prod }_{{θ}_{{k}_{end}}}$
PROCEDURE
  # history of synthetic demonstrations [symbol]
    = [ [symbol]  ᵤₛₑᵣ] # first demonstrations come from user
  k = 0
  do:
    #generate challenging scenarios for traffic policies
    Sₖ₊₁^{challenging} = ScenarioGenerator( [symbol]  , Π_{θ}_{ᵢ})
    #simulate traffic for those scenarios [symbol]
    ₖ₊₁^{synthetic} = { }
    for scencario Sⱼ in Sₖ₊₁^{challenging}
      # generate all traffic agent tarjectories
      Γⱼ = RolloutTraffic(Sⱼ, Π_{θ}_{ₖ})
      # gather traffic demonstrations [symbol]
      ₖ^{synthetic} = [symbol]  ₖ^{synthetic}∪{(SⱼΓⱼ)} [symbol]
    = concatenate( [symbol]  , [symbol] ₖ^{synthetic})
    # score traffic demonstrations
    Scoreₖ = Scoring( [symbol]  ₜᵣᵢₐₗₛ, Π_{θ}_{ₖ})
    #Update traffic policies based PUGAIL Gail objective
    Π_{θ}_{ₖ₊₁} ← PUGAIL(Π_{θ}_{ₖ}, [symbol]  ₜᵣᵢₐₗₛ, [symbol]  ᵤₛₑᵣ, [symbol]   ₑ)
    k = k + 1
While Scoreₖ < Score_{theshold}
```

### Step 3: Target Policy Fine Tuning

Once traffic policies Π_{θ} are fine-tuned on target locations we can fine-tune the target policies through massive interactions with the traffic on target locations. Increasingly challenging scenarios for the target policies π_{α}^{target} are generated with scenario generator from scenarios of user demonstrations Dᵤₛₑᵣ. Demonstration Dₜᵣᵢₐₗₛ generated by target policy π_{α}^{target} interacting with traffic on challenging scenarios are used to update target policy parameters denoted α based on target policy's own training method denoted Train_{target}. Note that in case the traffic is responsible for failure, it still possible to exploit traffic demonstrations to fine tune the traffic based on step 2 and restart target policy training from there.

An example schematic code for target policy fine-tuning is shown below as Algorithm 2.

Algorithm 2 target policy fine tuning

```
INPUTS:
  fine tuned traffic policies Π₀
  few user demonstrations [symbol]  ᵤₛₑᵣ = {(Sᵢ, Γᵢ^{user})}i∈ [symbol]   ᵤₛₑᵣ
  target poliy training method TRAIN_{target}
  target policy πₐ^{target}
OUTPUT :
  fine tuned target policy πₐ^{target}
PROCEDURE:FineTuneTargetPolicy
  # history of synthetic demonstrations [symbol]
  = [ [symbol]  ᵤₛₑᵣ] # first demonstrations come from user
  k = 0
  do
    #generate challenging scenarios for target policies
    Sₖ₊₁^{challenging} = ScenarioGenerator( [symbol]  , πₐ^{target}) [symbol]
    ₜᵣᵢₐₗₛ = { }
    #rollout target policy on generated scenario
    for sceneario Sⱼ in Sₖ₊₁^{challenging}
      # generate all traffic agent trajectories
      Γₖ, τ_{target} =
      RolloutTraffic(Sₖ^{challenging}, Π₀ᵢ xπₐ^{taregt})
      #gather whole simulation rollout [symbol]
ₜᵣᵢₐₗₛ = [symbol]  ₜᵣᵢₐₗₛ ∪{(Sⱼ, τ_{target})}
    Scoreₖ[πₐ^{taregt}] = Scoring( [symbol]  ₜᵣᵢₐₗₛ, {πₐ^{taregt}})
    Scoreₖ[Π₀] = Scoring( [symbol]  ₜᵣᵢₐₗₛ, Π₀})
    if Scoreₖ[Π₀] >
    scoreₘᵢₙ^{traffic} and Scoreₖ[πₐ^{target}] < scoreₘᵢₙ^{target}:
      πₐ^{taregt} = TRAIN_{target}(πₐ^{taregt}, [symbol]  ₜᵣᵢₐₗₛ)
    elif Scoreₖ[Π₀ᵢ] < scoreₘᵢₙ^{traffic}
      finetuneTraffic ( [symbol]  ᵤₛₑᵣ ∪ [symbol]   ₜᵣᵢₐₗₛ)
while πₐ^{taregt} < scoreₘᵢₙ^{target}
```

In the following additional information regarding the individual step is provided.

### PUGAIL Training Procedure

In order to fine tune traffic policies

$${\prod }_{θ} = {\{ {π}_{{θ}_{i}} \}}_{i ∈ N} ,$$

PUGAIL training procedure leverage few demonstration Dᵤₛₑᵣ collected by real users during their travels on target locations as well as synthetic demonstrations D^{synthetic} generated by traffic policies on challenging scenarios. Note that the size of Dᵤₛₑᵣ is much smaller than D^{synthetic}. As scenarios in D^{synthetic} have no associate expert trajectories, applying directly the MAIRL algorithm on D^{synthetic}∪D^{user} would result in poor performance because the dataset is highly unbalanced.

Additionally as ground truth is missing, it would be unfair to consider a priori that traffic policies cannot produce at all realistic transitions (oₜ,aₜ,oₜ₊₁) on new synthetic scenarios by assigning negative labels as they are already expected to generalize after MAIRL step and as we do not know how human drivers would have done on those situations. Therefore the original problem is reformulated into a positive unlabeled learning problem where the key difference is that traffic agent trajectories are considered as a mixture of expert and apprentice demonstrations. Practically the objective of the discriminator of the original problem is expressed as:

L_{D}^{PU}=max(−β [symbol] [log(D_{ϕ}(o,a,o′)]−η [symbol] [log(D_{ϕ(}o,a,o′)])+η [symbol] [log(1−D_{ϕ}(o,a,o′)]

Where η represent the positive class prior and β>0 according to [Xu et al, 2019]. As the set of positive labels D^{user} is still smaller than the unlabeled D^{synthetic} we tune positive class prior η according to the ratio between real and synthetic scenario to alleviate the unbalance. Given this new objective we alternate discriminator and policy update as before and obtain after multiple steps fine-tuned target policies

$${\prod }_{θ} = {\{ {π}_{{θ}_{i}} \}}_{i ∈ N}$$

that interact safely on various scenarios built upon target locations.

### Safety and Confidence Scoring

In order to evaluate whether a set of driving policies

$${\prod }_{θ} = {\{ {π}_{{θ}_{i}} \}}_{i ∈ N}$$

are safe and confident relative to a set of a diving scenario {Sₖ}_{k∈I}_{_{scenarios}} we compute a safety and confidence score for traffic agent or target policy in each episode generated in simulation. The final score is a weighted sum of individual score each based on specific aspects of driving trajectories as proposed by [Shalev-Shwartz et al, 2017]:
safety metrics: driving policy safety can be estimated on a set of driving scenarios based on several criteria like collision rate, traffic rule infractions, minimum safe distance, rate of jerk, off-road driving rate, lateral shift to centerlines
confidence metrics: the confidence of a driving policy can be estimated with proxy metric like time to goal which is expected to reduce once the agent get more confident or time to collision which is also expected to reduce as agent get more confident

### Challenging Scenario Generation

In order to generate various challenging scenarios on target geographical locations to train either traffic policies Π_{θ} during the second phase or target policies π_{α}^{target} during the third phase we introduce a scenario generator module. Note that scenario generator leverage scenarios of Dᵤₛₑᵣ progressively collected by users on target locations as seeds to generate new scenarios. Indeed this enable to diversify consistently the set of scenarios from common situations to very uncommon situations with a chosen coverage. Note that a driving scenario can be characterized by a finite list of parameters; based on the associate traffic flow. The traffic flow is based a traffic flow graph composed of a set of traffic nodes that generate agents at specific frequency. Each generated agent has its own initial physical configuration i.e. initial location, speed; destination, driving policy and driving style depending on driving policy. All those parameters can be perturbed under specific simple constrains that keep the traffic consistent (i.e. two agents cannot be spawned at same location and same time). The Scenario generator seeks the minimal sequence of bounded perturbations that leads to scenarios on which driving policies Π have low safety and confidence score. Here driving policies Π can represent traffic policies Π_{θ} or target policy {π_{α}^{target}}. During the search, the driving policies trainable weights are fixed. We use a reinforcement learning based procedure to learn, a scenario perturbation policy denoted π_{perturbation} that minimize the average cumulative safety and confidence score score Σₚ₌₀^{P}score(Π,Sₚ)) over the sequence of generated scenarios. Note that only a finite number of perturbation denoted P can be applied for each trials. We use an off policy method to learn π_{perturbation} like DQN [see Mnih et al, 2013] with a replay buffer B that stores transitions of the following form (S,δ, score(Π,S′),S′) where S is the current scenario, δ the perturbation to be applied, S′ the resulting scenario after perturbation and score(Π,S′) the safety and confidence score for driving policies Π over scenario S′:

An example schematic code for challenging scenario generation is shown below as Algorithm 3.

Algorithm 3 Challenging scenarios generation

```
INPUTS:
  driving policies to challenge Π
  original demonstartion [symbol]  ᵤₛₑᵣ = {(Si, [symbol] )} [symbol]
  Pₘₐₓ maximal number of perturbation by episod
  N :number of episods of scenario perturbations
  | [symbol]   |: buffer size
OUTPUTS:
  challenging scenarios [symbol]
PROCEDURE: ScenarioGenerator
  Init Buffer of perturbated scenarios [symbol]
  ← [symbol]
  do
    Repeat N times
      p = [symbol] [symbol]
      Get a scenario seed
      sample ( [symbol]   : [symbol] , scoreₖ, Sₖ₊ᵢ)~ [symbol]
      ᵤₛₑᵣ according uniform pobability
        p = 0, [symbol]  = [symbol]
        While p < [symbol]   : [symbol]
          generate challenging scenarios for target policies [symbol]
          δₚ =
            $\{ \begin{matrix}{π}_{perturbation} ( {\tilde{𝒮}}_{p} ) & exploitation with probability α \\ uniform distribution over perturbation space & exploiration with probability ( 1 - α )\end{matrix}$
          \tilde{S}ₚ₊₁ =
          ApplyPerturbation( [symbol]  , [symbol]  ) #zero pertubation if perturbation is inconsistent [symbol]
          = RolloutTraffic(\tilde{S}ₚ₊₁, Π)
          Scoreₚ = Scoring(\tilde{S}ₚ₊₁, Γₚ₊₁, Π)

[symbol]

          concatenate(r,(\tilde{S}ₚ,δₚ,Scoreₚ₊₁, \tilde{S}ₚ₊₁))
        #dump trajectory in buffer [symbol]
        ← r
    Train π^{perturbation} on replay buffer [symbol]  with DQN such as
      nₖ₊₁^{perturbation} =
      argmax [symbol]  _{perturbation} − [symbol]   |Σₚ₌₁^{p} Scoreₚ|
    #Reduce exploration [symbol]
    = ExponentialDecay(α)
  while [symbol]  |Σₚ₌₁^{P} Scoreₚ| > CumScoreₘᵢₙ
  return scenarios in buffer [symbol]
indicates data missing or illegible when filed
```

### References

[Bhattacharyya et al 2019] Modeling Human Driving Behavior through Generative Adversarial Imitation Learning Raunak Bhattacharyya, Blake Wulfe Derek Phillips, Alex Kuefler, Jeremy Morton Ransalu Senanayake Mykel Kochenderfer 2019
[Wang et al 2021] Decision Making for Autonomous Driving via Augmented Adversarial Inverse Reinforcement Learning Pin Wang, Dapeng Liu, Jiayu Chen, Hanhan Li, Ching-Yao Chan 2021
[Jeon et al 2021] Scalable and Sample-Efficient Multi-Agent Imitation Learning Wonseok Jeon, Paul Barde, Joelle Pineau, Derek Nowrouzezahrai 2021
[Zolna et al 2019] Task-Relevant Adversarial Imitation Learning Konrad Zolna, Scott Reed, Alexander Novikov, Sergio Gomez Colmenarejo, David Budden, Serkan Cabi, Misha Denil, Nando de Freitas, Ziyu Wang 2019
[Xu et al 2019] Positive unlabeled reward learning Danfei Xu, Misha Denil 2019
[Song et al 2018] Multi-Agent Generative Adversarial Imitation Learning Jiaming Song, Hongyu Ren, Dorsa Sadigh, Stefano Ermon 2018
[Li et al 2017] InfoGAIL: Interpretable Imitation Learning from Visual Demonstrations Yunzhu Li, Jiaming Song, Stefano Ermon 2017
[Fu et al 2018] Learning robust rewards with adversarial inverse reinforcement learning Justin Fu, Katie Luo, Sergey Levine 2017
[Orsini et al 2021] What Matters for Adversarial Imitation Learning? Manu Orsini, Anton Raichuk, Léonard Hussenot, Damien Vincent, Robert Dadashi, Sertan Girgin, Matthieu Geist, Olivier Bachem, Olivier Pietquin, Marcin Andrychowicz 2021
[Mnih et al 2013] Playing Atari with Deep Reinforcement Learning Volodymyr Mnih, Koray Kavukcuoglu, David Silver, Alex Graves, Ioannis Antonoglou, Daan Wierstra, Martin Riedmiller 2013
[Shalev-Shwartz et al 2017] On a Formal Model of Safe and Scalable Self-driving Cars Shai Shalev-Shwartz, Shaked Shammah, Amnon Shashua Mobileye, 2017

What is claimed is:

1. A method of updating a target driving policy for an autonomous vehicle at a target location, the method comprising:
obtaining, by the vehicle, vehicle driving data at the target location;
transmitting, by the vehicle, the obtained vehicle driving data and a current target driving policy for the target location to a data center; and
receiving, by the vehicle, an updated target driving policy from the data center, the updated target driving policy being obtained based on traffic simulations performed by the data center for the target location using the vehicle driving data.

2. The method according to claim 1, wherein the steps of obtaining vehicle driving data at the target location, transmitting the obtained vehicle driving data to the data center, and receiving the updated target driving policy from the data center based on traffic simulations using the vehicle driving data are repeated one or more times.

3. The method according to claim 1, the method further comprising:
obtaining general driving data and general traffic policies; and
using the general driving data and the vehicle driving data to adapt the general traffic policies to the target location.

4. The method according to claim 3, the method further comprising, prior to receiving, by the vehicle, the updated target driving policy:
performing, by the data center, the traffic simulations for the target location using the vehicle driving data to obtain the updated target driving policy; and
transmitting, by the data center, the updated target driving policy to the vehicle,
wherein the step of performing traffic simulations for the target location is based on the adapted general traffic policies.

5. The method according to claim 1, wherein the updated target driving policy comprises an updated set of target driving policy parameters.

6. The method according to claim 1, wherein performing traffic simulations comprises training the current target driving policy to improve a confidence measure or a safety measure.

7. The method according to claim 1, the method further comprising:
prior to receiving, by the vehicle, the updated target driving policy:
performing, by the data center, the traffic simulations for the target location using the vehicle driving data to obtain the updated target driving policy; and
transmitting, by the data center, the updated target driving policy to the vehicle
generating different traffic scenarios by modifying an initial traffic scenario obtained from the vehicle driving data,
wherein the traffic simulations for the target location are performed with the generated different traffic scenarios.

8. The method according to claim 7, wherein modifying the initial traffic scenario comprises at least one of:
increasing a number of agents in the traffic scenario;
modifying a velocity of an agent in the traffic scenario;
modifying an initial position and/or direction of an agent in the traffic scenario; and
modifying a trajectory of an agent in the traffic scenario.

9. The method according to claim 1, wherein the target location is described by map data of a geographically limited area.

10. The method according to claim 1, wherein vehicle driving data at the target location are further obtained from one or more further vehicles.

11. A data center, the data comprising:
a receiver configured to receive, from a vehicle, vehicle driving data at a target location and a current target driving policy for the target location;
processing circuitry configured to perform traffic simulations for the target location using the vehicle driving data to obtain an updated target driving policy; and
a transmitter configured to transmit the updated target driving policy to the vehicle.

12. The data center according to claim 11, wherein the processing circuitry is further configured to use general driving data and the vehicle driving data to adapt general traffic policies to the target location.

13. The data center according to claim 11, wherein the processing circuitry is further configured to perform traffic simulations for the target location based on the adapted general traffic policies.

14. The data center according to claim 11, wherein the updated target driving policy comprises an updated set of target driving policy parameters.

15. The data center according to claim 11, wherein the processing circuitry is further configured to train the current target driving policy to improve a confidence measure and/or a safety measure.

16. The data center according to claim 11, wherein the processing circuitry is further configured to generate different traffic scenarios by modifying an initial traffic scenario obtained from the vehicle driving data; and to perform the traffic simulations for the target location with the generated different traffic scenarios.

17. The data center according to claim 16, wherein the processing circuitry is configured to modify the initial traffic scenario by at least one of:
increasing a number of agents in the traffic scenario;
modifying a velocity of an agent in the traffic scenario;
modifying an initial position and/or direction of an agent in the traffic scenario; or
modifying a trajectory of an agent in the traffic scenario.

18. The data center according to claim 11, wherein the target location is described by map data of a geographically limited area.

19. The data center according to claim 11, wherein the receiver are further configured to receive vehicle driving data at the target location from one or more further vehicles.

20. A system, the system comprising:
a vehicle configured to obtain vehicle driving data at a target location, and configured to transmit the obtained vehicle driving data and a current target driving policy for the target location to a data center; and
the data center according to claim 11.

21. The system according to claim 20, configured to repeatedly perform the steps of obtaining vehicle driving data at the target location, transmitting the obtained vehicle driving data to the data center, performing traffic simulations for the target location using the vehicle driving data to obtain an updated target driving policy, and transmitting the updated target driving policy to the vehicle.

22. A non-transitory computer-readable storage medium comprising computer readable instructions for, when run on a computer, performing the steps of the method according to claim 1.
